(19) United States
(12) Patent Application Publication
(10) Pub. No.: US 2003/0102505 A1
(43) Pub. Date: Jun. 5, 2003

(54) Overvoltage protection device

(76) Inventors: Jeremy Paul Smith, Wellingborough (GB); Stephen Wilton Byatt, Bedordshire (GB)

Correspondence Address: KLEIN, O'NEILL & SINGH, 2 Park Plaza, Ste. 510, Irvine, CA, 92614, US

(21) Appl. No.: 10/305,890

(22) Filed: Nov. 27, 2002

(30) Foreign Application Priority Data
Nov. 30, 2001 (GB) 0218665.7

(51) Int. Cl. H01L 29/76

(52) U.S. Cl. 257/335

(57) ABSTRACT

A body of semiconductor material for use in forming a low voltage surface breakdown protection device comprises a substrate having upper and lower surfaces, and a PN junction formed between first (16) and second (14) regions of the body in which in the intended operation of the device reverse breakdown of the junction occurs. The substrate forms the first region (16) which is of lower impurity concentration than the second region (14) and the second (14) region extends to the upper surface of the substrate (16). First and second edge breakdown regions (42, 44) extending to the upper surface of the substrate are provided in the first region (16). They are of the same conductivity type as and of higher impurity concentration than the first region (16). An insulating layer (46) is formed on the upper surface of the substrate over the junction between the second edge breakdown region (26) and the second region (14) for protecting the interface between the insulating layer (46) and the edge breakdown region (26) during subsequent processing. The insulating layer (46) has a low concentration of impurities thereby to restrict current flow adjacent the interface between the insulating layer (46) and the edge breakdown region (26).

### BACKGROUND OF THE INVENTION

1. Field of the Invention

The present invention relates to an overvoltage protection device.

2. Description of the Prior Art

There are in existence a wide range of semiconductor devices which are designed to protect communication equipment from overvoltages which can occur on telephone lines as a result of, for example, lightening strikes and AC power surges. Many of these semiconductor devices are based on a four layer PNPN structure which is designed to switch quickly from a blocking state to a high conduction state when the voltage across the device exceeds a predetermined threshold level.

Two important characteristics of an overvoltage protection device are the peak voltage before switching occurs, known as the breakover voltage V_{BO} and its surge capability. In the past, switching has typically been designed to occur at a maximum breakover voltage of between 70 V and 400 V for analogue communication lines. However, the increased emphasis on digital communications has led to a requirement for maximum breakover voltages of less than 40 V and typically as low as 15 V.

The switching of such devices is usually designed to occur due to the avalanche breakdown of a specific PN junction within the structure. The voltage at which this occurs is substantially equal to the V_{BO} of the device and is determined by the doping concentrations on each side of the junction. Higher doping concentrations result in lower breakover voltages although where the ratio of the two concentrations is very high it is the lower concentration of the two that governs the voltage at which avalanche initiates.

Generally, breakdown in the bulk of the device is preferred to breakdown at the surface. As a result, many existing structures contain an implanted pad region positioned vertically below the base region which is used to define the V_{BO} of the device. However, the minimum breakover voltage which can be achieved using such a structure is about 50 V because the highest concentration achievable at the interface of the base and pad regions is relatively low.

### BRIEF SUMMARY OF THE INVENTION

The present invention seeks to provide an improved overvoltage protection device and method of making same.

Accordingly, the present invention provides a body of semiconductor material for use in forming a low voltage surface breakdown protection device, the body comprising a substrate having upper and lower surfaces, and a PN junction formed between first and second regions of the body in which in the intended operation of the device reverse breakdown of the junction occurs; wherein: said substrate forms said first region; the first region is of lower impurity concentration than the second region; said second region extends to said upper surface of said substrate; an edge breakdown region of the same conductivity type as and of higher impurity concentration than the first region is provided in the first region and extends to the upper surface of said substrate and into said second region; and a first insulating layer is formed on said upper surface of said substrate over the junction between said edge breakdown region and said second region for protecting the interface between said insulating layer and said edge breakdown region during subsequent processing.

In a preferred form of the invention said insulating layer has a low concentration of impurities thereby to restrict current flow adjacent the interface between said insulating layer and said edge breakdown region. Alternatively, said insulating layer is undoped.

Advantageously, said edge breakdown region comprises first and second regions extending to the upper surface of said substrate; said second edge region extends into said second region and underlies said undoped insulating layer and said first edge region lies outside said insulating layer.

In a preferred form of the invention said edge breakdown regions are of the same conductivity type and a second, doped insulating layer is formed on said first insulating layer. The doped insulating layer is preferably phosphorous rich.

The present invention also provides a low voltage surface breakdown protection device having a semiconductor body according to the invention.

The present invention also provides a method of manufacturing a semiconductor low voltage surface breakdown protection device comprising the steps of: providing a subtrate of a first conductivity type having upper and lower surfaces and forming a first region: forming a base region of a second conductivity type in said substrate, said base region extending from said upper surface and forming a PN junction with said substrate, wherein said junction extends to said upper surface; and forming an emitter region in said base region and an edge breakdown region in said substrate; wherein said emitter region and said edge breakdown region are of the same conductivity type as and of higher doping concentration than said first region; and prior to forming said emitter and edge breakdown regions a first insulating layer is formed on said upper surface extending across said junction thereby to protect the interface between said insulating layer and said edge breakdown region during subsequent formation of said emitter and edge breakdown regions.

Preferably, said insulating layer has a low concentration of impurities thereby to restrict current flow adjacent the interface between said insulating layer and said edge breakdown region. Alternatively, said insulating layer is undoped.

In a preferred form of the invention said edge breakdown region is formed as first and second regions extending to the upper surface of said substrate; said second edge region extends into said second region and underlies said insulating layer; and said first edge region lies outside said insulating layer. Said edge breakdown regions are of the same conductivity type.

Prior to forming said emitter and edge breakdown regions a second, doped insulating layer is formed on said first insulating layer. The doped insulating layer is preferably phosphorous rich and said emitter region and said edge breakdown region are formed by diffusion of impurities from said second insulating layer.

Said first and second insulating layers are conveniently oxide layers.

### BRIEF DESCRIPTION OF THE DRAWINGS

The present invention is further described hereinafter, by way of example, with reference to the accompanying drawings, in which:

FIG. 1 is a diagrammatic cross section of a conventional vertical breakdown overvoltage protection device;

FIG. 2 is a diagrammatic cross section of an existing low voltage, surface breakdown device;

FIGS. 3 to 8 show the steps in the fabrication of the device of FIG. 2;

FIG. 9 is a cross sectional view of the breakdown region of FIG. 2 that includes an illustration of current flow during turn-on;

FIG. 10 is a plan view of the portion of the device shown in FIG. 9 which illustrates the location and form of damage caused by a typical destructive surge; and

FIGS. 11 to 18 show the steps in the fabrication of an overvoltage protection device according to the present invention.

### DETAILED DESCRIPTION OF THE PREFERRED EMBODIMENT

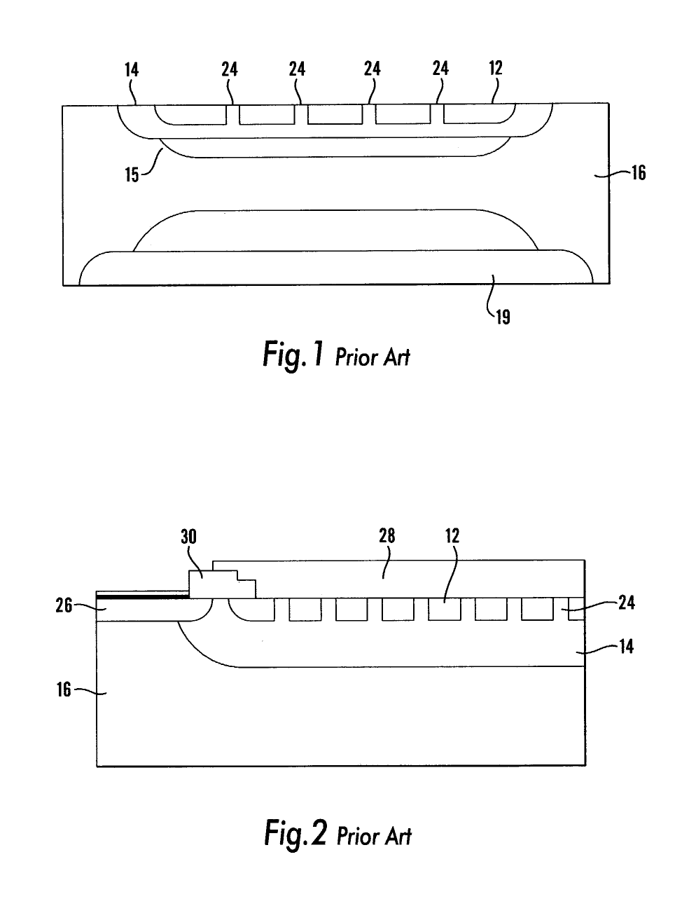

FIG. 1 is one example of a conventional four layer (PNPN) diode 8 which has an emitter region 12 of highly doped N-type conductivity in a base region 14 of less highly doped but still heavily doped P-type conductivity. A heavily doped buried region 15, referred to as a blanket pad, of N-type conductivity is formed beneath the base region 14 at the junction of the base region 14 and a lightly doped region 16 of N-type conductivity which forms the bulk of the semiconductor device.

An anode region 19 of heavily doped P-type conductivity is located on the underside of the region 16.

The emitter region 12 is penetrated by a number of small area shorting dots 24 of the material of the base region 14. These are distributed over the area of the junction between the cathode region 12 and the base region 14 to provide a resistor connection across that junction and give the device a relatively high but controlled holding current.

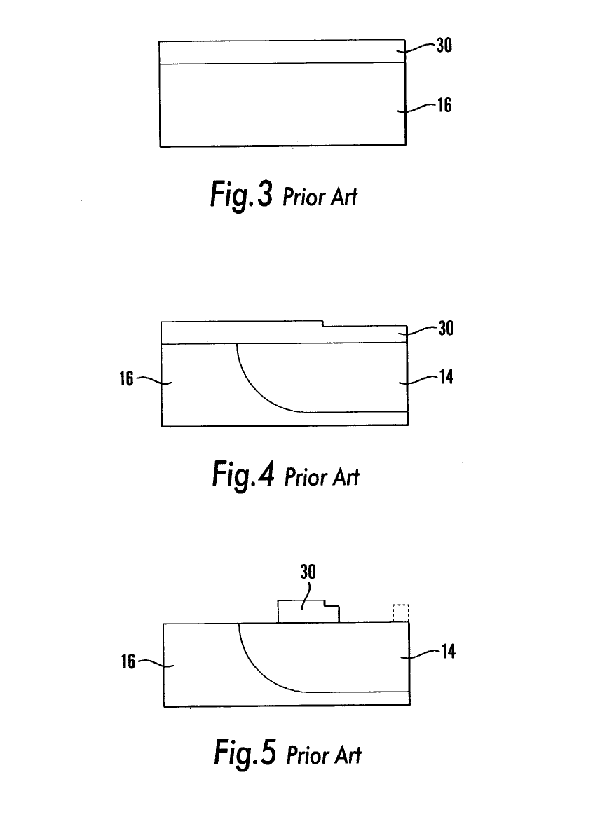

Referring to FIG. 2, this is a diagrammatic cross section of a portion of a conventional low voltage, surface breakdown four layer PNPN diode 10. This has an emitter region 12 of highly doped N⁺-type conductivity in a base region 14 of less highly doped but still heavily doped P-type conductivity. A lightly doped region 16 of N-type conductivity forms the bulk of the semiconductor device.

The emitter region 12 is penetrated by a number of small area shorting dots 24 of the material of the base region 14. These are distributed over the area of the junction between the emitter region 12 and the base region 14 to provide a resistor connection across that junction and give the device a relatively high controlled holding current.

The device also has an edge surface region 26 which extends into the base region 14 and is of the same N⁺-type conductivity and doping concentration as the emitter region 12. A metalisation layer 28 covers the surface of the device but is insulated from the edge region 26 by an oxide layer 30.

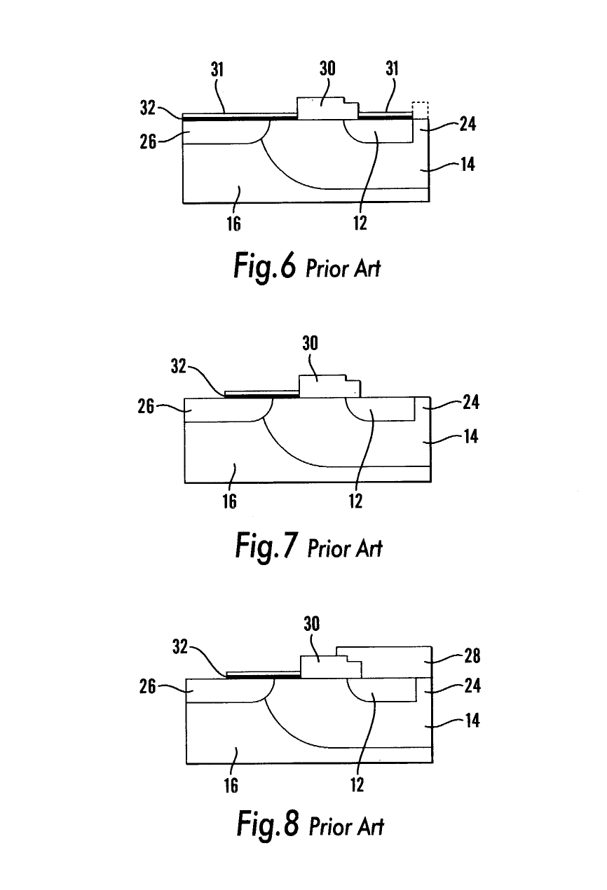

The fabrication of the portion of the device shown in FIG. 2 is illustrated in FIGS. 3 to 8 which show a cross section of a portion of the device.

Firstly, the oxide layer 30 is formed on the upper surface of the substrate 16 (FIG. 3) and a portion is etched away over the central area of the substrate following which boron is diffused into the substrate 16 to form the base region 14 (FIG. 4).

The oxide layer 30 is further etched to form the emitter mask (FIG. 5). The emitter region 12 and edge region 26 are then formed by diffusion of phosphorous from a phosphorous rich oxide layer 31, which is deposited on the upper surface. The shorting dots 24 are also formed at this time (FIG. 6).

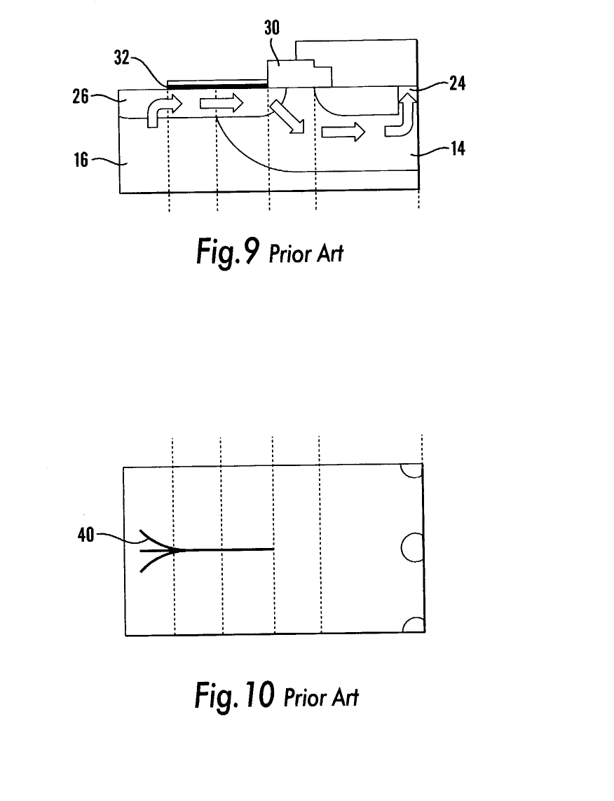

The contact windows for the device are then etched and metalisation applied to produce the device of FIG. 2 (FIGS. 7 and 8) which achieves a lower breakover voltage by using avalanche breakdown at the surface of the device where doping concentrations can be maximised. The breakover region of the device of FIG. 2 is shown in detail in FIG. 9. FIG. 9 also shows the path of the current during breakover from the substrate 16 through the edge region 26, the base region 14 and the shorting dots 24.

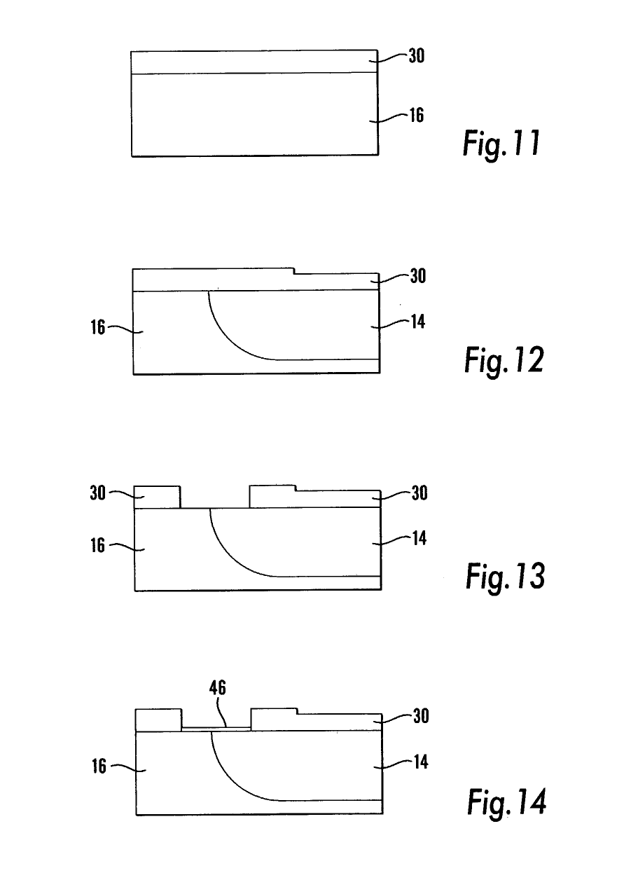

The structure is capable of providing breakover voltages between about 8 V and 20 V. However, the breakover voltage in the device of FIG. 2 is dependent mainly on the P-type doping concentration of the base region 14 and the conditions under which the emitter region 12 and the edge region 26 are deposited. In addition, the quality of the phosphorous rich oxide to silicon interface 32 is very poor due to the high concentration of impurities present during its formation. During fast voltage surges a large current can flow adjacent to the oxide silicon interface layer 32 before the device actually turns on. This large parallel current, in conjunction with the poor quality interface region, can cause excessive heating and irreversible damage to the device. In addition to this, spots of abnormally high phosphorous concentration can exist adjacent to the base region. Such “hot spots” cause preferential turn on and hence filimentation. A diagrammatic illustration of typical fast surge damage is shown in FIG. 10 where marks 40 are formed on the semiconductor surface as a result of melting of the semiconductor and insulator from the excessive heating. The damage signature of FIG. 10 corresponds directly to the interface region 32 and is also indicative of filimentation.

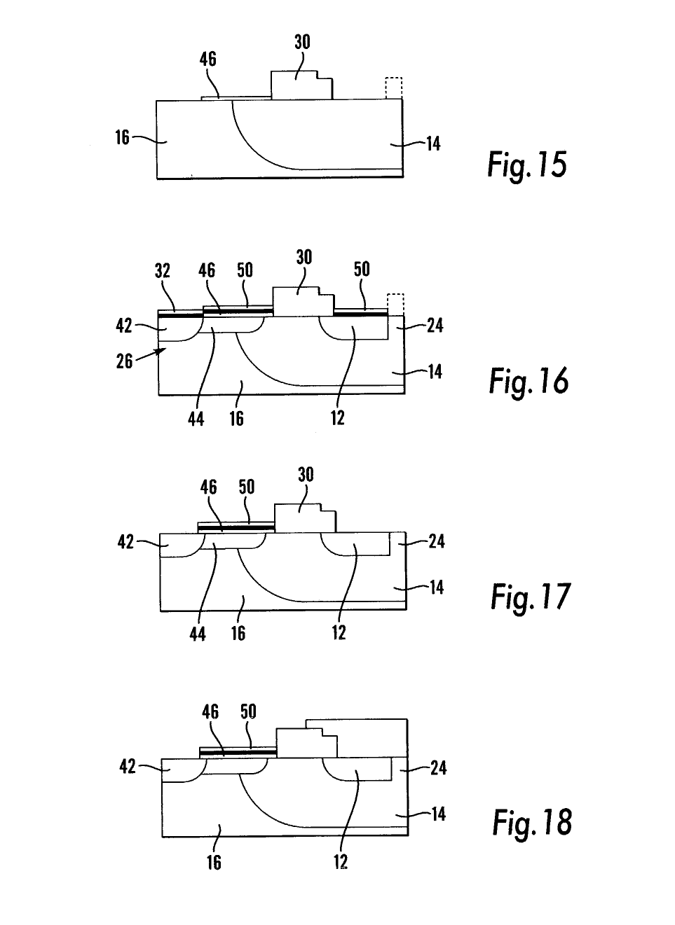

Referring now to FIGS. 11 to 18 these show the steps in the construction of a preferred form of semiconductor device according to the present invention.

The steps are similar to those described with reference to FIGS. 3 to 8 with the oxide 30 and base 14 being formed in the same manner (FIGS. 11 and 12). However, before the emitter is formed, a thin layer of oxide 46 is created over the junction between the base 14 and the substrate 16 on the surface of the device (FIGS. 13 and 14). This thin oxide is left during the subsequent stage where the emitter windows are opened (FIG. 15). As a result, the edge region 26 is formed as two distinct regions 42 and 44 during the following phosphorus diffusion (FIG. 16). With the region 44 extending into the base region 14, the region 44 is thinner than the region 42 since it is formed underneath the thin oxide layer 46. As can be seen from the drawings, the region 42 may penetrate slightly underneath the layer 46 during diffusion but predominantly, the region 44 underlies the layer 46 whilst the region 42 does not.

The oxide layer 46 is sufficiently thin (approximately 1400 Angstroms) that it allows the bulk of the dopant to penetrate into the silicon, as a result of which low breakover voltages can be achieved.

A phosphorous rich oxide layer 32, 50 is deposited on the upper surface and the emitter and edge regions 12, 42, 44 are formed by diffusion of phosphorous from this layer (FIG. 16). The shorting dots 24 are also formed at this time. However, when the emitter and edge regions 12, 42, 44 are deposited, the phosphorus rich oxide layer 50 forms an interface with the electrically inactive shielding oxide layer 46. Hence the silicon to oxide interface of the breakdown region, between the oxide layer 46 and the edge regions 44, 42 is protected from contamination and/or damage. This interface region is, therefore, of a much higher quality than in the device of FIG. 2 where the phosphorus rich oxide 32 forms an interface directly with the silicon. In addition to this the thin oxide layer prevents the formation of localised areas of abnormally high phosphorous concentration adjacent to the buried region 14, thus removing the risk of preferential turn on and filimentation.

The edge region 44 can thus support a much higher parallel surge current than can the device of FIGS. 2 and 9.

The contact windows for the device are then etched and metalisation applied (FIGS. 17 and 18).

Because of the protection afforded by the oxide layer 46, excessive heating and damage are not caused by current flows adjacent the interface. As a result, a much higher rating of surge current at breakover can be supported or alternatively the device can be made smaller for the same rating as the known device of FIGS. 2 and 9.

It is also possible for the thickness of the thin oxide region 46 to be optimised independently of the emitter and base doping characteristics. This allows an additional degree of control over the breakover voltage without the degradation of other electrical parameters.

Typical doping concentrations for the various regions are as follows:

Region 14—10¹⁷ to 10¹⁸

Region 32—10¹⁸ to 10¹⁹

Region 44—10²² to 10²¹

1. A body of semiconductor material for use in forming a low voltage surface breakdown protection device, the body comprising:
a substrate having upper and lower surfaces;
first and second regions in the body forming a PN junction in which reverse breakdown of the junction occurs in the intended operation of the device;
wherein:
said substrate forms said first region;
the first region is of lower impurity concentration than the second region;
said second region extends to said upper surface of said substrate;
an edge breakdown region of the same conductivity type as and of higher impurity concentration than the first region is provided in the first region and extends to the upper surface of said substrate and into said second region;
and a first insulating layer is formed on said upper surface of said substrate over the junction between said edge breakdown region and said second region for protecting the interface between said insulating layer and said edge breakdown region during subsequent processing.

2. A semiconductor body as claimed in claim 1 wherein said insulating layer has a low concentration of impurities thereby to restrict current flow adjacent the interface between said insulating layer and said edge breakdown region.

3. A semiconductor body as claimed in claim 1 wherein said insulating layer is undoped.

4. A semiconductor body as claimed in claim 1 wherein:
said edge breakdown region comprises first and second regions extending to the upper surface of said substrate;
said second edge region extends into said second region and underlies said insulating layer and said first edge region lies outside said insulating layer.

5. A semiconductor body as claimed in claim 4 wherein said edge breakdown regions are of the same conductivity type.

6. A semiconductor body as claimed in claim 1 wherein a doped insulating layer is formed on said first insulating layer.

7. A semiconductor body as claimed in claim 6 wherein said doped insulating layer is phosphorous rich.

8. A body of semiconductor material for use in forming a low voltage surface breakdown protection device, the body comprising:
a substrate having upper and lower surfaces;
first and second regions in the body forming a PN junction in which reverse breakdown of the junction occurs in the intended operation of the device;
wherein:
said substrate forms said first region;
the first region is of lower impurity concentration than the second region;
said second region extends to said upper surface of said substrate;
an edge breakdown region of the same conductivity type as and of higher impurity concentration than the first region is provided in the first region and extends to the upper surface of said substrate and into said second region;
and a first insulating layer is formed on said upper surface of said substrate over the junction between said edge breakdown region and said second region for protecting the interface between said insulating layer and said edge breakdown region during subsequent processing;
said first insulating layer has a low concentration of impurities thereby to restrict current flow adjacent the interface between said insulating layer and said edge breakdown region;
said edge breakdown region comprises first and second regions of the same conductivity type extending to the upper surface of said substrate;
said second edge region extends into said second region and underlies said insulating layer and said first edge region lies outside said insulating layer;
and a doped insulating layer is formed on said first insulating layer.

9. A low voltage surface breakdown protection device having a semiconductor body as claimed in claim 1.

10. A method of manufacturing a semiconductor low voltage surface breakdown protection device comprising the steps of:
providing a substrate of a first conductivity type having upper and lower surfaces and forming a first region:
forming a base region of a second conductivity type in said substrate, said base region extending from said upper surface and forming a PN junction with said substrate, wherein said junction extends to said upper surface;
and forming an emitter region in said base region and an edge breakdown region in said substrate;
wherein said emitter region and said edge breakdown region are of the same conductivity type as and of higher doping concentration than said first region;
and prior to forming said emitter and edge breakdown regions a first insulating layer is formed on said upper surface extending across said junction thereby to protect the interface between said insulating layer and said edge breakdown region during subsequent formation of said emitter and edge breakdown regions.

11. A method as claimed in claim 10 wherein said insulating layer has a low concentration of impurities thereby to restrict current flow adjacent the interface between said insulating layer and said edge breakdown region.

12. A method as claimed in claim 10 wherein said insulating layer is undoped.

13. A method as claimed in claim 10 wherein:
said edge breakdown region is formed as first and second regions extending to the upper surface of said substrate;
said second edge region extends into said second region and underlies said insulating layer;
and said first edge region lies outside said insulating layer.

14. A method as claimed in claim 13 wherein said edge breakdown regions are of the same conductivity type.

15. A method as claimed in claim 10 wherein, prior to forming said emitter and edge breakdown regions a second, doped insulating layer is formed on said first insulating layer.

16. A method as claimed in claim 15 wherein said doped insulating layer is phosphorous rich.

17. A method as claimed in claim 16 wherein said emitter region and said edge breakdown region are formed by diffusion of impurities from said second insulating layer.

18. A method as claimed in claim 15 wherein said second insulating layer is an oxide layer.

19. A method as claimed in claim 10 wherein said first insulating layer is an oxide layer.

20. A method of manufacturing a semiconductor low voltage surface breakdown protection device comprising the steps of:
providing a substrate of a first conductivity type having upper and lower surfaces and forming a first region:
forming a base region of a second conductivity type in said substrate, said base region extending from said upper surface and forming a PN junction with said substrate, wherein said junction extends to said upper surface;
and forming an emitter region in said base region and an edge breakdown region in said substrate;
wherein said emitter region and said edge breakdown region are of the same conductivity type as and of higher doping concentration than said first region;
and prior to forming said emitter and edge breakdown regions a first insulating layer is formed on said upper surface extending across said junction thereby to protect the interface between said insulating layer and said edge breakdown region during subsequent formation of said emitter and edge breakdown regions;
and wherein said insulating layer has a low concentration of impurities thereby to restrict current flow adjacent the interface between said insulating layer and said edge breakdown region.
said edge breakdown region is formed as first and second regions of the same conductivity type extending to the upper surface of said substrate;
said second edge region extends into said second region and underlies said insulating layer;
and prior to forming said emitter and edge breakdown regions a second, doped insulating layer is formed on said first insulating layer.
